(19) United States
(12) Patent Application Publication
(10) Pub. No.: US 2024/0222316 A1
(43) Pub. Date: Jul. 4, 2024

(54) HYBRID BONDING WITH SONIC ENERGY

(71) Applicant: Adeia Semiconductor Bonding Technologies Inc., San Jose, CA (US)

(72) Inventors: Pawel Mrozek, San Jose, CA (US); Gaius Gillman Fountain, JR., Youngsville, NC (US)

(21) Appl. No.: 18/400,697

(22) Filed: Dec. 29, 2023

Related U.S. Application Data
(60) Provisional application No. 63/478,149, filed on Dec. 31, 2022.

(51) Int. Cl. H01L 23/00

(52) U.S. Cl. CPC H01L 24/80; H01L 2224/80205; H01L 2224/80895; H01L 2224/80896

(57) ABSTRACT

A method of forming direct metal bonds between a first device and a second device is provided. The method may include heating a workpiece to a temperature between 40 C and 150 C, and directing sonic energy towards the heated workpiece. Here, the workpiece may include the first device and the second device directly bonded to the first device through a dielectric material interface.

### CROSS-REFERENCE TO RELATED APPLICATIONS

This application claims priority to U.S. Provisional Application 63/478,149, filed Dec. 31, 2022 which is incorporated herein by reference in its entirety.

### FIELD

The present disclosure generally relates to advanced integrated circuit (IC) packaging and, more particularly, to hybrid bonding methods for heterogeneous integration and processing systems for performing the methods.

### BACKGROUND

Heterogeneous integration (HI) refers to the incorporation of dissimilar devices into a single device package. The dissimilar devices may be different sizes, have different functionalities, comprise different materials, and are often manufactured using different technologies. Typically, the devices are interconnected using flip-chip, micro-bumping, or other technologies that form relatively short connections or by bonding the input/output (I/O) pads without the use of an adhesive or intervening connector, i.e., direct bonding. Advanced hybrid bonding methods may further include forming direct bonds between the devices' dielectric surfaces before heating the devices to form the direct bonds between the I/O pads. Such hybrid bonding methods may be advantageously used when smaller pad size, reduced pitch, and increased pad density is desired. Unfortunately, direct hybrid bonding of devices formed on different types of substrates has sometimes proven challenging, particularly when the substrate materials have substantially mismatched CTEs (coefficients of thermal expansion). This is because heating the devices to even relatively low temperatures e.g., 150 C or more, may cause the previously formed dielectric joints to fail before the metal-to-metal bonds can form.

Accordingly, there is a need in the art for lower temperature direct hybrid bonding methods and processing systems for performing the methods,

### SUMMARY

In one implementation, a method of forming direct hybrid bonds between a first device and a second device is provided. The method may include heating a workpiece to a temperature between 40 C and 150 C, and directing sonic energy towards the heated workpiece. Here, the workpiece may include the first device and the second device directly bonded to the first device through a dielectric material interface.

In another implementation, a heterogeneous integrated (HI) device is provided. The HI device may include a first device comprising a first semiconductor material, and a second device comprising a second semiconductor material. The coefficient of thermal expansion (CTE) of the first semiconductor material may be two times or greater than a CTE of the second semiconductor material. The first and second devices are directly bonded at a dielectric material interface, and the first and second devices are electrically connected through a plurality of direct hybrid bonds.

In another implementation, a processing system for forming direct hybrid bonds is provided. The processing system may include a container sized to hold a semiconductor wafer-shaped workpiece in a horizontal orientation and a wave propagating liquid that covers the workpiece. The container may include a support surface and one or more sidewalls extending upward from the support surface to define a volume. The processing system may further include one or more transducers disposed above and positioned to direct ultrasonic energy towards the support surface, and an actuator for moving the one or more transducers relative to the support surface.

In one implementation, a method of forming direct hybrid bonds in a workpiece is provided. Here, the workpiece generally includes a plurality of first devices directly bonded a plurality of second devices, e.g., by direct dielectric bonds. The method may include positioning the workpiece on a workpiece support, heating the workpiece to a processing temperature between 40 C and 150 C, positioning one or more ultrasonic transducers over a first region of the workpiece, transmitting sonic energy towards the first region, positioning the one or more ultrasonic transducers over a second region of the workpiece, and transmitting sonic energy towards the second region.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1-2 include schematic cross-sectional views of bonded devices that illustrate aspects of a conventional hybrid bonding process.

FIG. 3 is a stress-strain graph that illustrates a theoretical change in a plastic deformation point with sonic energy.

FIG. 4 includes schematic cross-sectional views of the heterogeneous devices of FIG. 2 at different stages of an ultrasonic nano-forging hybrid bonding process, according to an embodiment.

FIGS. 5A and 5B is a schematic cross-sectional view of an integrated device formed using the method illustrated in FIG. 3, according to an embodiment.

FIGS. 6-9 illustrate example processing systems configured to perform aspects of the method described in relation to FIG. 3, according to some embodiments.

FIGS. 10-11 are a flow diagrams of processing methods, according to some embodiments.

The figures herein depict various embodiments of the invention for purposes of illustration only. It will be appreciated that additional or alternative structures, systems, and methods may be implemented within the principles set out by the present disclosure.

### DETAILED DESCRIPTION

Embodiments herein are generally directed to methods of forming direct hybrid bonds using sonic energy and relatively low processing temperatures, e.g., less than about 150 C, devices formed using the methods, and apparatus and software for performing the methods. As used herein, the term “workpiece” may include individual substrates, devices, or assemblies of substrates and/or devices at any stage of a device manufacturing process. For example, a workpiece may include a singulated first device directly bonded to a singulated second device in a die-to-die bonding scheme, a plurality of singulated second devices directly bonded to a plurality of pre-singulation first devices in a die-to-wafer bonding scheme, or a plurality of pre-singulation first devices directly bonded to a plurality of pre-singulation second devices in a wafer-to-wafer bonding scheme. The term “device” typically includes a substrate and any material layers, features, and/or electronic devices formed thereon, therein, or therethrough. The term “substrate” generally includes one or more supporting materials upon which elements of an electronic device are fabricated or attached and can include portions of the one or more supporting materials before or after singulation of the individual devices, e.g., the term “substrate” may include a pre-singulation wafer or post-singulation portions of a wafer. Unless otherwise noted, the term “device” as used herein may include any material layers features formed on, in, or through a substrate at any point in the device fabrication and assembly process, whether or not the material layers, devices, or features are present in the finished device and whether or not the substrate comprises a wafer or a singulated portion of a wafer.

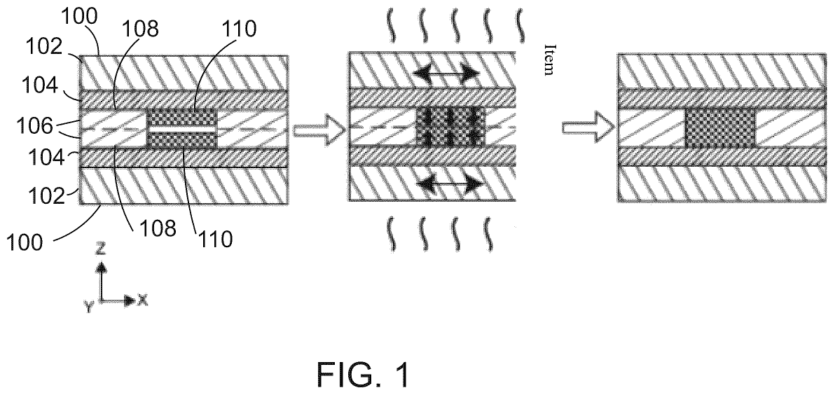

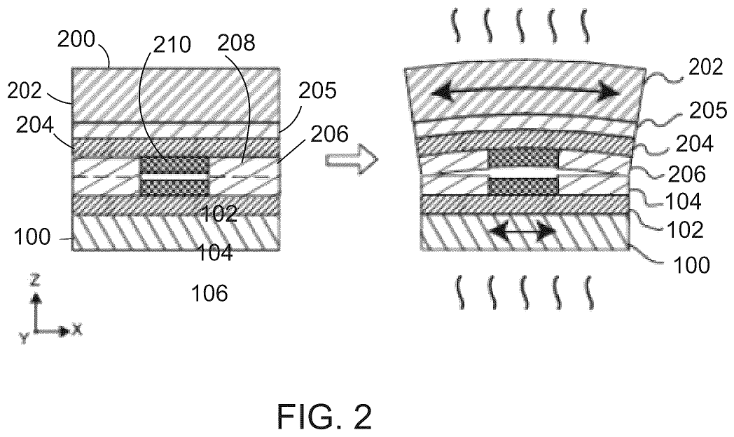

Generally, the methods include forming direct bonds between dielectric surfaces of at least two devices to form a workpiece and directing sonic energy toward the workpiece to form direct hybrid bonds between the at least two devices. The application of sonic energy to the workpiece enables the formation of the direct hybrid bonds at significantly lower processing temperatures than used typically used for hybrid bonding, such as illustrated in FIGS. 1-2.

FIG. 1 illustrates a hybrid bonding method that uses thermal anneal to form direct hybrid bonds between bond pads of substantially similar devices. Here, each device 100a-b includes a substrate 102, such as a silicon wafer, a plurality of front-end-of-line FEOL device elements (not shown), such as transistors, resistors, or capacitors formed on or in the substrate, a plurality of back-end-of-line (BEOL) layers 104, and an input/output (I/O) layer 106. Here, the I/O layer includes a dielectric material 108 and metal bond pads 110 disposed in and recessed from a field surface of the dielectric material. The hybrid bonding method generally includes bonding the devices by preparing, aligning, and contacting the dielectric materials at ambient room temperature and heating the bonded devices to form metallurgical bonds between the metal bond pads.

Typically, the bonded devices are heated to a processing temperature of about 150° C. or more so that the aligned metal bond pads expand in the Z-direction at a greater rate than the bonded surrounding dielectric materials, which creates a contact force at the bond pad interface. It is believed that metallurgical bonds are formed at the bond pad interface when the contact force between bond pads is severe enough to cause plastic deformation of the bond pad material. The contact force is determined, at least in part, by the change in volume of the bond pad material as the bonded devices are heated and are thus determined, at least in part, by the processing temperature.

The method illustrated in FIG. 1 advantageously allows for increased bond strength, reduced pitch between bond pads, smaller bond pad dimensions, and increased bond pad density when compared to conventional I/O schemes, such as those using wire bonds. The method is commonly used to form 3D-IC devices where the to-be-bonded devices are substantially similar, such as a memory device stack, or the bulk substrate materials of the to-be-bonded devices have substantially similar or “matched” CTEs in the desired processing temperature range.

FIG. 2 illustrates the hybrid bonding method of FIG. 1 using heterogeneous devices, each formed using substrate materials having substantially different or “mismatched” CTEs, in the desired processing temperature range. In one example, a first device includes a first substrate 100, such as a silicon wafer, BEOL layers 102, and an I/O layer 106. The second device 200 includes a second substrate 202 formed of a material different than the first substrate, BEOL layers 204, and an I/O layer 206 comprising a dielectric layer 208 having metal bond pads 210 disposed therein. For example, the second substrate may comprise a non-silicon semiconductor material, a compound semiconductor material, or may comprise a dielectric substrate having a semiconductor material 205 or compound semiconductor material formed thereon, such as a sapphire substrate having a III-V semiconductor, e.g., GaAs, epitaxially formed thereon. Sapphire substrates typically have a CTE (in the X-Y plane) that is about 3× or more than the CTE of the silicon substrate when heated to temperatures 150 C or more, where the CTE is a fractional change in length of the material (in the X-Y plane) per degree of temperature change. The first and second devices may be bonded together using direct bonds formed between the dielectric surfaces at about room temperature, as described above in FIG. 1. However, when the bonded devices are heated to form the direct hybrid bonds, the different rates of expansion between the sapphire and silicon substrates in the X-Y plane at temperatures greater than about 80 C can combine to cause significant distortion of the respective substrates. Unfortunately, this distortion may cause stress-induced failure of the direct bond joint at the dielectric material interface before metallurgical bonds between the bond pads can be formed.

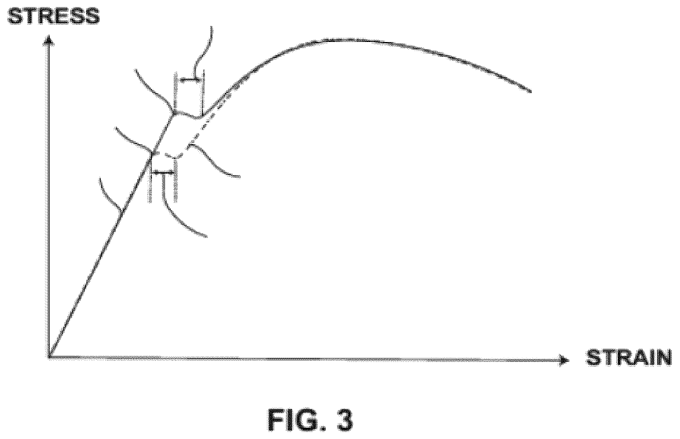

Without intending to be bound by theory, it is believed that the application of sonic energy “acoustically softens” of the bond pad material to lower the yield point and cause a corresponding shift in the contact force required to induce plastic deformation, such as illustrated in FIG. 3. The lowered contact force needed to induce plastic deformation can be achieved with smaller changes in the bond pad material volume and thus lower anneal temperatures than used in the method described in relation to FIGS. 1-2. In some implementations, desired metallurgical bonds between bond pads may be advantageously formed at temperatures less than about 150° C. and more than about 40° C., such as about 149° C. or less, 140° C. or less, 130° ° C. or less, 120° C. or less, 110° C. or less, 100° C. or less, 90° C. or less, or for example, about 80° C. or less or between about 50° C. and about 120° ° C., such as between about 50° C. and about 100° C. Thus, the ultrasonic nano-forging methods described herein may be used to facilitate direct hybrid bonding of heterogeneous devices, as well as direct hybrid bonding of devices having relatively low thermal budgets, such as about 100° C. or below.

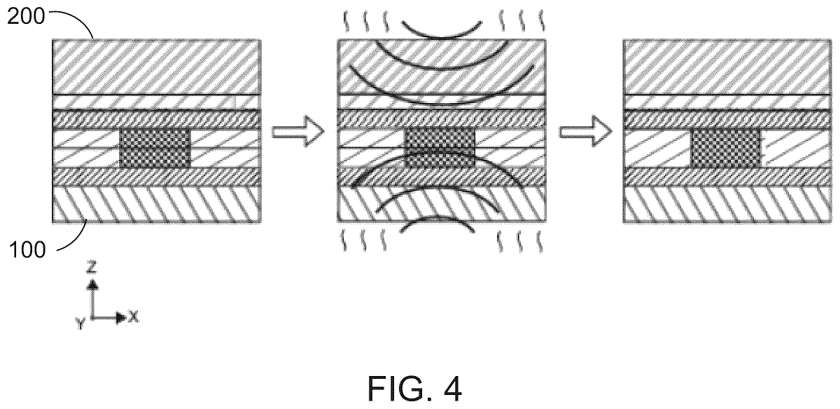

FIG. 4 illustrates a hybrid bonding method that uses sonic energy to form direct hybrid bonds, e.g., copper to copper bonds, at the relativity low processing temperatures described above. The workpiece typically includes one or more first devices and one or more second devices directly bonded to one or more second devices. For example, the workpiece may include a singulated first device directly bonded to a singulated second device in a die-to-die bonding scheme, a plurality of singulated second devices directly bonded to a plurality of first devices in a die-to-wafer bonding scheme, or a plurality of first devices directly bonded to a plurality of second devices in a wafer-to-wafer bonding scheme.

In some embodiments, the method includes forming the workpiece. Forming the workpiece may include preparing the one or more first devices and the one or more second devices for direct dielectric bonding and aligning and contacting prepared surfaces to form the direct dielectric bonds. Preparing the surfaces for direct bonding may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the surfaces using a chemical mechanical polishing (CMP) process. Activating and terminating the surfaces with the desired species may include exposing the surfaces to a nitrogen-based plasma, exposing the surfaces to an aqueous ammonia solution in a wet cleaning process, or both. In some implementations, directly bonding the dielectric material surfaces of the first and second devices includes bringing the prepared and aligned surfaces into direct contact under ambient temperature and pressure conditions.

In some embodiments, preparing the surfaces includes using the CMP process to remove an overburden of interconnect material, e.g., copper, from the field of the dielectric layer. Without intending to be bound by theory, it is believed that the direct dielectric bonds formed at ambient (room) temperatures may form as relatively weak intermolecular attractions, i.e., Van Der Waals bonds, that strengthen into stronger covalent bonds with time and/or increased temperatures. As described above in relation to FIG. 1, heating the workpiece to processing temperatures of 150 C or more can cause the metal features to expand in volume and impart a force sufficient to interfere and break the dielectric bonds. Thus, in the process illustrated in FIG. 1, the metal features are purposely recessed from the dielectric surface by a distance greater than about 5 nm. However, here the metal features may not see volume expansion sufficient to disrupt the dielectric bonds due to the lower processing temperatures. Thus, in some embodiments, the CMP process is controlled so that the metal bond pads are substantially coplanar with the surface of the dielectric layer or protrude upwardly therefrom. As used herein, substantially coplanar includes metal bond pads that are recessed from the surface of the dielectric layer by an average distance of about 1 nm or less.

Here, the method generally includes heating a workpiece to a processing temperature between about 40 C and 150 C and directing sonic energy towards the heated workpiece to form the direct metal bonds. In some embodiments, the first device comprises a first substrate or a portion of a first substrate, the second device comprises a second substrate or a portion of a second substrate, and the first and second substrates are formed of CTE mismatched materials such that the CTE of the first substrate is 2× or greater than a CTE of the second substrate. For example, in some implementations, the first substrate may be formed of crystalline silicon, e.g., a silicon wafer, and the second substrate may be formed of non-silicon semiconductor material, such as germanium. In some embodiments, the second substrate may be formed of a compound semiconductor, such as III-V, II-VI, IV-IV materials, or a dielectric material, such as sapphire, having a non-silicon semiconductor or a compound semiconductor epitaxially formed thereon or bonded thereto. In some embodiments, the second substrate is formed of a ceramic material, e.g., a metal oxide material, metal nitride material, metal carbide material, or a combination thereof. In some embodiments, both the first and second substrates are formed of materials other than crystalline silicon.

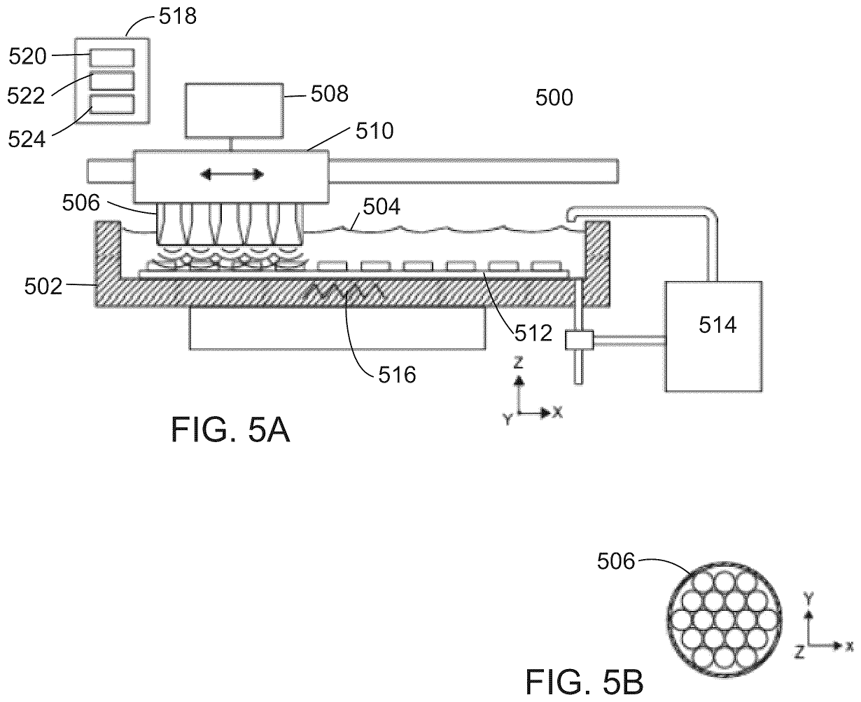

FIGS. 5A-5B schematically illustrate one implementation of a processing system that may be used to perform aspects of the ultrasonic nano-forging method. As shown in FIG. 5A, the processing system 500 includes a workpiece holder 502, e.g., a container, for holding a workpiece in a wave propagating fluid 504, a transducer array 506 disposed above and facing towards the workpiece holder, an ultrasonic generator 508 coupled to the transducer array, a motion stage 510 for moving the transducer array relative to the workpiece 512, a fluid source 514, a heater 516 for heating the workpiece to a desired processing temperature, and a controller 518 configured with a processor 520, memory 522, and instructions 524 stored in memory that when executed by the processor cause the processing system to perform aspects of the methods described herein. As shown, the heater is a resistive element disposed in or in thermal contact with the supporting surface of the workpiece holder. In some implementations, a heated liquid may be delivered from the fluid source.

The workpiece holder may be sized and shaped (when viewed from top down) to hold a workpiece formed in a device to wafer or wafer to wafer direct bonding scheme and have a depth sufficient to cover the workpiece with the liquid. In some implementations, the workpiece is fixedly secured to the workpiece holder, e.g., by use of a clamp and fasteners (not shown), to reduce standing wave propagation through the workpiece during processing. In some implementations, the workpiece is unsecured or lightly secured so that workpiece may vibrate relative to the workpiece holder.

The transducer array includes a plurality of transducers disposed in an arrangement that has a smaller area when viewed from the bottom up (FIG. 5B) than a surface of the workpiece. The transducer array is coupled to an ultrasonic generator which may be configured to generate substantially similar ultrasonic waveforms from each transducer or may be configured to generate at least one of waveform having one or more different wave characteristics, such as a different frequency, a different amplitude, or a different phase, than a waveform provided by a different transducer. In some embodiments, the transducer array may be configured as a phased array where one or more characteristics of the individual waves can be adjusted to deliver a beam of focused sonic energy to a desired region of the workpiece. In some implementations, the fluid source delivers a wave propagating liquid, such as water, to the workpiece holder and at least a portion of the transducer array is immersed in the wave propagating liquid. In some implementations, the liquid has a boiling point greater than 100 C. In some implementations, the liquid may comprise a non-aqueous organic liquid, e.g., an oil.

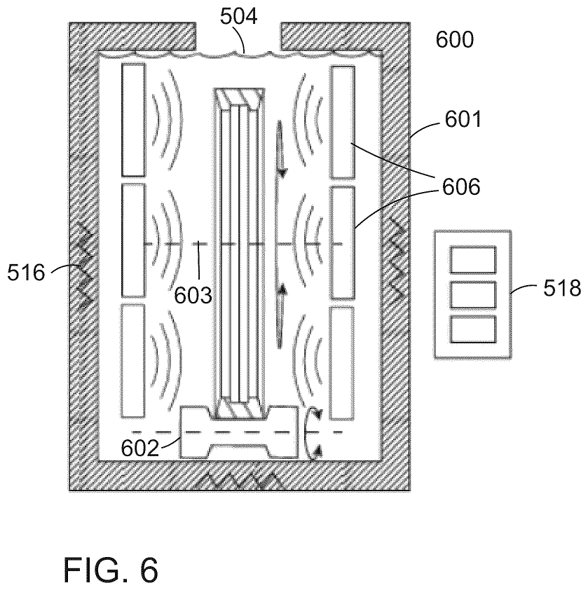

FIG. 6 schematically illustrates another implementation of a processing system that may be used to perform aspects of the ultrasonic nano-forging method. In FIG. 6, the processing system 600 includes a chamber 601 comprising wave propagating liquid 604, a workpiece holder 602, such as a clamp, configured to support the workpiece 612 in a vertical orientation and move the workpiece about a horizontal axis of rotation 603, e.g., by use of one or more roller wheels 605, and least two transducers 606 disposed on opposite sides of the workpiece holder. The at least two transducers may form a portion of the chamber walls, may be disposed outside of the chamber walls, or may be at least partially immersed in the fluid as shown. Here, the at least two transducers are shown as a plurality of transducer plates that remain stationary as the workpiece is moved relative thereto. In some implementations, the at least two transducers may include at least two transducer arrays, such as shown in FIG. 5B, each positioned to direct sonic energy towards the workpiece. It is contemplated that the system may further or alternatively include any one or combination of the features shown in the other processing systems disclosed herein. For example, the system may include one or more ultrasonic wave generators, a controller, and a fluid source as described in relation to FIG. 5A. In some embodiments each of the transducer plates, arrays, or individual transducers within an array are independently controllable by use of an individual wave generator.

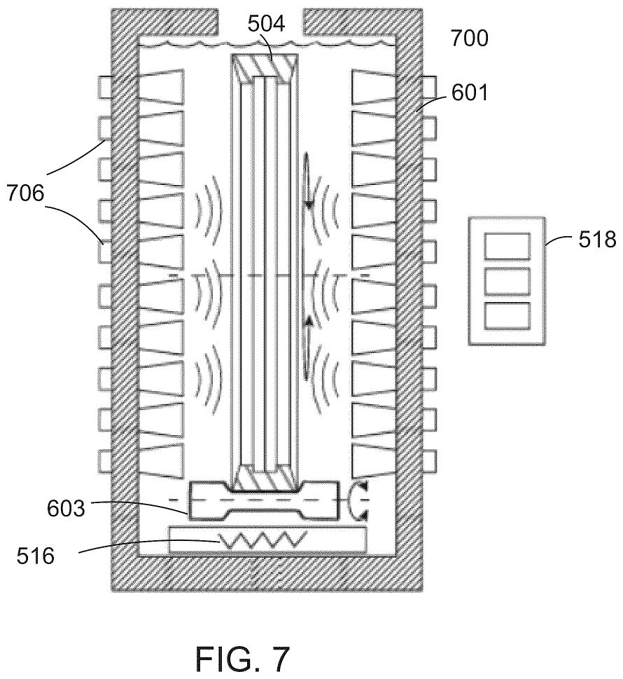

FIG. 7 illustrates a processing system substantially similar to the processing system of FIG. 6, further comprising a plurality of independently controllable transducers. During processing, each transducer may be used to direct a different amount of sonic energy towards a different region of the workpiece as it is rotated about the horizontal axis 603.

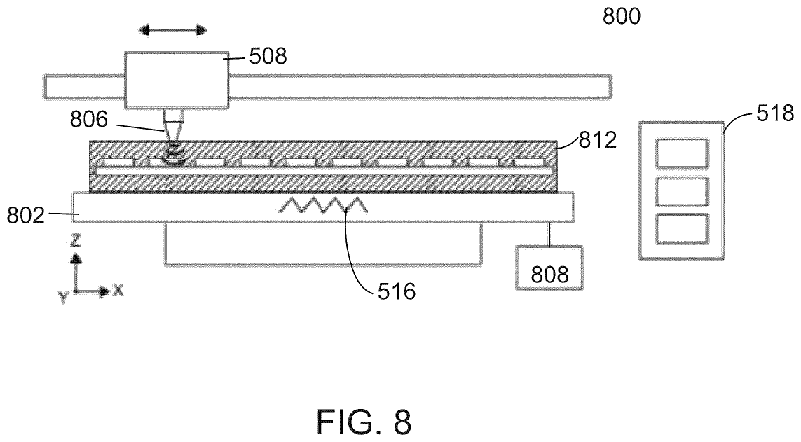

FIG. 8 illustrates a processing system configured for use with a solid or semi-solid wave propagating medium. Here, the processing system 800 includes a heated chuck 802 for supporting the workpiece 812, the chuck 802 having a controller 808 configured to rotate the workpiece or move the workpiece in X-Y directions. The workpiece 812 is at least partially disposed in a solid or semi-solid wave propogating medium, such as a polymer or epoxy, and a transducer 806 positioned above the workpiece is configured to direct sonic energy towards desired regions thereof.

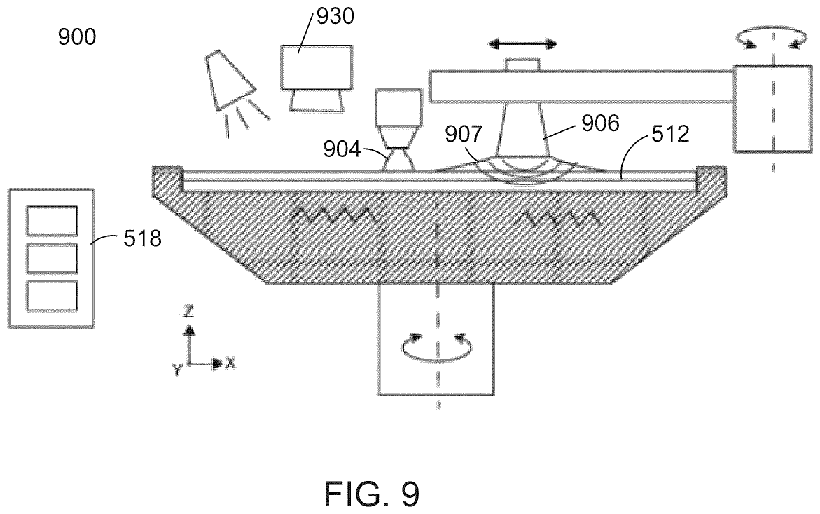

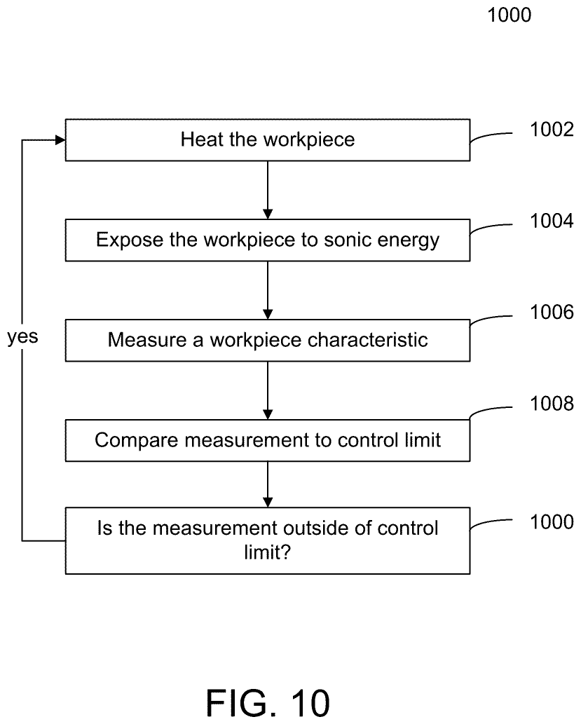

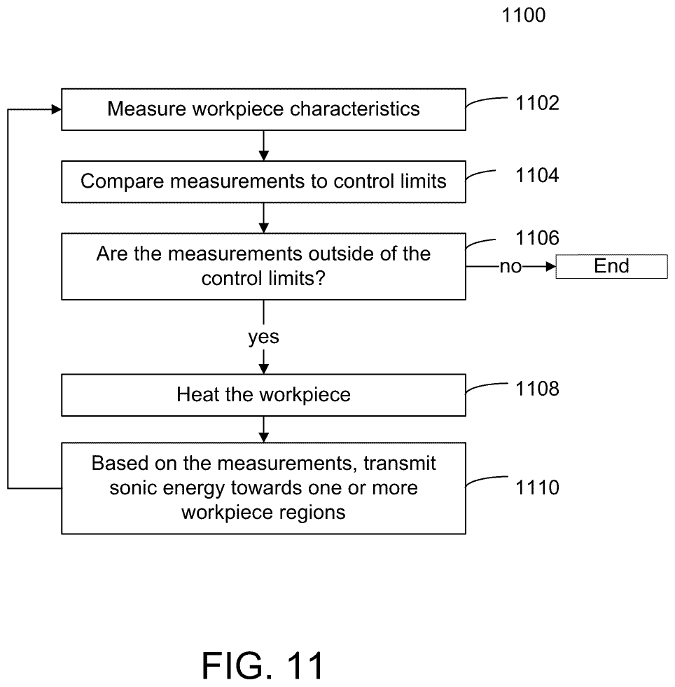

FIG. 9 illustrates a processing system 900 where the wave propagating medium includes a viscous liquid 904 and a transducer 906 positioned in close proximity to the workpiece 512 in order to transmit sonic energy through a meniscus 907 formed with the viscous liquid. The transducer is positioned over the workpiece by use of an arm and an actuator that moves the arm about a vertical axis. The processing system optionally includes a radiant heat source 916, e.g., a lamp, and a sensor 930, such as camera, for monitoring the ultrasonic nano-forging process. It is contemplated that the features of the processing systems described above may be used in combination with the features of any of the other processing systems for use performing the methods illustrated in FIGS. 10 and 11.

Further embodiments are described in the items that follow:
Item 1, a method of forming direct hybrid bonds between a first device and a second device, the method comprising: (a) heating a workpiece to a temperature between 40 C and 150 C, wherein the workpiece comprises the first device and the second device directly bonded to the first device through a dielectric material interface; and (b) directing sonic energy towards the heated workpiece.
Item 2, the method of item 1, wherein: the first device comprises a first substrate; the second device comprises a second substrate; and a CTE of the first substrate is 2× or greater than a CTE of the second substrate. Item 3, the method of item 2, wherein: the first substrate comprises crystalline silicon; and the second substrate comprises a non-silicon semiconductor, a compound semiconductor, or a dielectric having a non-silicon semiconductor or a compound semiconductor formed thereon or bonded thereto. Item 4, the method of item 2, wherein the first substrate comprises crystalline silicon and the second substrate comprises sapphire.
Item 5, the method of item 1, wherein the sonic energy is transmitted to the workpiece through a liquid having a boiling point greater than 100 C. Item 6, the method of item 1, wherein: the workpiece comprises an at least partially solid material disposed over one or both of the first and second devices; and the sonic energy is transmitted to the first and second devices through the at least partially solid material. Item 7, the method of item 1, wherein: the sonic energy is directed towards the first and second devices from a transducer assembly directly contacting the workpiece or one or more solid materials disposed in direct contact with the workpiece. Item 8, the method of item 1, wherein the workpiece comprises: a plurality of first devices each comprising a portion of a first substrate; and a plurality of singulated second devices directly bonded to the plurality of first devices.
Item 9, the method of item 1, wherein the workpiece comprises: a plurality of first devices each comprising a portion of a first substrate; and a plurality of second devices directly bonded to the plurality of first devices, the plurality of second devices each comprising a portion of a second substrate. Item 10, the method of item 1, wherein: the first and second devices each comprise metal features disposed in the dielectric material; and prior to (a), the metal features of the first device are in direct contact with the metal features of the second device or are separated from each other by about 2 nm or less. Item 11, the method of item 1, wherein the sonic energy has a frequency of about 20 kHz or more.
Item 12, the method of item 1, wherein (b) comprises: generating ultrasonic vibrations using one or more transducers; and transmitting the ultrasonic vibrations through a liquid disposed between the workpiece and the one or more transducers. Item 13, the method of item 12, further comprising: (c) concurrent with (b), moving the workpiece, the one or more transducers, or both to provide a relative scanning motion between the workpiece and the one or more transducers. Item 14, the method of item 12, further comprising: (d) concurrently with (b), periodically moving the workpiece, the one or more transducers, or both to provide a relative stepping motion between the workpiece and the one or more transducers.
Item 15, the method of item 12, further comprising: (e) moving the workpiece, the one or more transducers, or both; and (f) changing one or more processing parameters based on a relative position of the workpiece and the one or more transducers, wherein the one or more processing parameters determine an amount of sonic energy directed towards the workpiece. Item 16, the method of item 1, wherein the workpiece comprises a plurality of first devices and a plurality of second devices directly bonded to the plurality of first devices, and the method further comprises: (g) after (b), measuring one or more characteristics of the workpiece; (h) comparing the one or more characteristics to a process control limit; and (i) repeating (a) and (b) when the one or more characteristics are outside of the process control limit.
Item 17, the method of item 16, wherein the one or more characteristics comprises bond strength and/or voiding between the plurality of first devices and the plurality of second devices. 18, the method of item 16, wherein the one or more characteristics comprise electrical properties of direct hybrid bonds formed between the plurality of first devices and the plurality of second devices.
Item 19, a heterogeneous integrated device, comprising: a first device comprising a first semiconductor material; and a second device comprising a second semiconductor material, wherein: a CTE of the first semiconductor material is 2× or greater than a CTE of the second semiconductor material; and the first and second devices are electrically connected through a direct hybrid bonds formed therebetween. Item 20, the device of item 19, wherein the direct hybrid bonds comprise metal-to-metal bonds having a pitch of about 10 um or less. Item 21, the device of item 19, wherein the direct hybrid bonds comprise metal-to-metal bonds having an average diameter of about 10 um or less. Item 22, the device of item 19, wherein the first semiconductor material comprises crystalline silicon and the second semiconductor material comprises a compound semiconductor.
Item 23, a processing system for forming direct hybrid bonds, comprising: a container sized to hold a semiconductor wafer-shaped workpiece in a horizontal orientation and a wave propagating liquid that covers the workpiece, the container comprising a support surface and one or more sidewalls extending upward from the support surface to define a volume; one or more transducers disposed above and positioned to direct ultrasonic energy towards the support surface; and an actuator for moving the one or more transducers relative to the support surface.
Item 24, the processing system of item 23, wherein the one or more transducers comprises an array of transducers positioned so that at least a portion of the array is disposed in the container during workpiece processing. Item 25, the processing system of item 23, further comprising a heat source for maintaining the workpiece at a processing temperature. Item 26, the processing system of item 23, wherein the actuator comprises an X-Y stage.
Item 27, the processing system of item 23, further comprising a non-transitory computer-readable medium storing a set of instructions, the set of instructions that, when executed by one or more processors of the processing system, cause the processing system to: generate ultrasonic vibrations using the one or more transducers; transmit the ultrasonic vibrations through a liquid disposed between the workpiece and the one or more transducers. move the workpiece, the one or more transducers, or both; and change one or more processing parameters based on a relative position of the workpiece and the one or more transducers, wherein the one or more processing parameters determine an amount of sonic energy directed towards the workpiece.
Item 28, the processing system of item 27, wherein the set of instructions that, when executed by the one or processors, further cause the processing system to: heat the workpiece to a temperature between 40° ° C. and 150° ° C. Item 29. A processing system for forming direct hybrid bonds, comprising: a container sized to hold a semiconductor wafer-shaped workpiece in a vertical orientation, the container comprising a base and one or more sidewalls extending upward from the base to define a volume; one or more support elements for supporting the workpiece in the vertical orientation and rotating the workpiece about a horizontal axis; and one or more transducers disposed on opposite sides of a workpiece processing region, the one or more transducers each positioned to directed ultrasonic energy towards a workpiece disposed in the processing region.
Item 30, the processing system of item 29, wherein the one or more transducers comprises an array of transducer elements, one or more transducer plates, one or more transducer rods, or any combination thereof. Item 31, the processing system of item 29, wherein each of the one or more transducers is sized and positioned to direct ultrasonic energy at only a portion of the workpiece.
Item 32. A method of forming direct hybrid bonds, comprising: (a) positioning a workpiece on a workpiece support, the workpiece comprising a plurality of first devices directly bonded a plurality of second devices; (b) heating the workpiece to a processing temperature between 40 C and 150 C; (c) positioning one or more ultrasonic transducers over a first region of the workpiece; (d) transmitting sonic energy towards the first region; (e) positioning the one or more ultrasonic transducers over a second region of the workpiece; and (f)transmitting sonic energy towards the second region. Item 33, the method of item 32, further comprising: (g) before (a), determining the first and second regions based on one or more measurements of a workpiece characteristic.
Item 34, the method of item 33, wherein the workpiece characteristic comprises bond strength and/or voiding between the plurality of first devices and the plurality of second devices. Item 35, the method of item 33, wherein the workpiece characteristic comprises one or more electrical properties of direct hybrid bonds formed between the plurality of first devices and the plurality of second devices. Item 36, the method of item 33, wherein the sonic energy comprises focused ultrasonic waves.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the invention. Only the claims that follow are meant to set bounds as to what the present invention includes.

What is claimed is:

1. A method of forming direct hybrid bonds between a first device and a second device, the method comprising:
(a) heating a workpiece to a temperature between 40 C and 150 C, wherein the workpiece comprises the first device and the second device directly bonded to the first device through a dielectric material interface; and
(b) directing sonic energy towards the heated workpiece.

2. The method of claim 1, wherein:
the first device comprises a first substrate;
the second device comprises a second substrate; and
a CTE of the first substrate is 2× or greater than a CTE of the second substrate.

3. The method of claim 2, wherein:
the first substrate comprises crystalline silicon; and
the second substrate comprises a non-silicon semiconductor, a compound semiconductor, or a dielectric having a non-silicon semiconductor or a compound semiconductor formed thereon or bonded thereto.

4. The method of claim 2, wherein the first substrate comprises crystalline silicon and the second substrate comprises sapphire.

5. The method of claim 1, wherein the sonic energy is transmitted to the workpiece through a liquid having a boiling point greater than 100 C.

6. The method of claim 1, wherein:
the workpiece comprises an at least partially solid material disposed over one or both of the first and second devices; and
the sonic energy is transmitted to the first and second devices through the at least partially solid material.

7. The method of claim 1, wherein:
the sonic energy is directed towards the first and second devices from a transducer assembly directly contacting the workpiece or one or more solid materials disposed in direct contact with the workpiece.

8. The method of claim 1, wherein the workpiece comprises:
a plurality of first devices each comprising a portion of a first substrate; and
a plurality of singulated second devices directly bonded to the plurality of first devices.

9. The method of claim 1, wherein the workpiece comprises:
a plurality of first devices each comprising a portion of a first substrate; and
a plurality of second devices directly bonded to the plurality of first devices, the plurality of second devices each comprising a portion of a second substrate.

10. The method of claim 1, wherein:
the first and second devices each comprise metal features disposed in the dielectric material; and
prior to (a), the metal features of the first device are in direct contact with the metal features of the second device or are separated from each other by about 2 nm or less.

11. The method of claim 1, wherein the sonic energy has a frequency of about 20 kHz or more.

12. The method of claim 1, wherein (b) comprises:
generating ultrasonic vibrations using one or more transducers; and
transmitting the ultrasonic vibrations through a liquid disposed between the workpiece and the one or more transducers.

13. The method of claim 12, further comprising:
(c) concurrent with (b), moving the workpiece, the one or more transducers, or both to provide a relative scanning motion between the workpiece and the one or more transducers.

14. The method of claim 12, further comprising:
(d) concurrently with (b), periodically moving the workpiece, the one or more transducers, or both to provide a relative stepping motion between the workpiece and the one or more transducers.

15. The method of claim 12, further comprising:
(e) moving the workpiece, the one or more transducers, or both; and
(f) changing one or more processing parameters based on a relative position of the workpiece and the one or more transducers, wherein the one or more processing parameters determine an amount of sonic energy directed towards the workpiece.

16. The method of claim 1, wherein the workpiece comprises a plurality of first devices and a plurality of second devices directly bonded to the plurality of first devices, and the method further comprises:
(g) after (b), measuring one or more characteristics of the workpiece;
(h) comparing the one or more characteristics to a process control limit; and
(i) repeating (a) and (b) when the one or more characteristics are outside of the process control limit.

17. The method of claim 16, wherein the one or more characteristics comprises bond strength and/or voiding between the plurality of first devices and the plurality of second devices.

18. The method of claim 16, wherein the one or more characteristics comprise electrical properties of direct hybrid bonds formed between the plurality of first devices and the plurality of second devices.
